(19) United States
(12) Patent Application Publication
(10) Pub. No.: US 2012/0152331 A1
(43) Pub. Date: Jun. 21, 2012

(54) SOLAR BATTERY ASSEMBLY

(76) Inventor: Hui LUO, Shenzhen (CN)

(21) Appl. No.: 13/406,807

(22) Filed: Feb. 28, 2012

Related U.S. Application Data
(63) Continuation of application No. PCT/CN2010/076446, filed on Aug. 29, 2010.

(30) Foreign Application Priority Data
Aug. 31, 2009 (CN) 200910189696.6
Aug. 31, 2009 (CN) 200920204200.3

(51) Int. Cl. H01L 31/048

(52) U.S. Cl. 136/251

(57) ABSTRACT

A solar battery assembly, includes a light transmitting upper cover plate, a carrier, and a plurality of solar cells disposed between the light transmitting upper cover plate and the carrier. The solar cells are connected with the carrier via positive connection points and negative connection points. The plurality of solar cells are connected in series, in parallel or in combinations of both via the positive and negative connection points.

### CROSS-REFERENCE TO RELATED APPLICATIONS

The present application is a continuation of International Application No. PCT/CN2010/076446, filed Aug. 29, 2010, which claims priority to and benefits of Chinese Patent Application Nos. 200910189696.6 and 200920204200.3, both filed with the China Patent Office on Aug. 31, 2009, the entire contents of all of which are incorporated herein by reference.

### FIELD

The present disclosure relates to solar energy field, and more particularly to a solar battery assembly.

### BACKGROUND

With continuous consumption of limited traditional energy resources such as oil which resulted in serious pollution to the environment, utilization of wind and solar energy has become increasingly popular. Particularly, the abundance of solar energy with less geological restriction has rendered solar energy a hot and important research focus nowadays.

An existing solar battery assembly may normally be formed as follows: laminating a glass, a binding layer, a plurality of solar cells, a binding layer and a back sheet; hot-pressing the laminated layers obtained hereinabove; and sealing the above laminated assembly. Presently, a single solar cell may provide a voltage of about 0.5V, which may be insufficient and difficult for practical application, whereas an outdoor tool may need a operating voltage of at least 12 V. Thus, the plurality of solar cells may currently be connected in series-parallel combinations to provide the operating voltage. For example, a current-extraction electrode of a solar cell may be welded with an electrode grid line on the surface of the next solar cell. However, the existing solar cell having a narrow electrode grid line may lead to difficulties in positioning the welding point during welding and manufacturing. Meanwhile, long current-extraction electrodes may be designed in order to ensure stable connections between the solar cells.

Conventionally, a welding strip, such as a tin strip or a copper strip with a tin coating, may be used, which may increase the production cost. Furthermore, to arrange the solar cells orderly and to avoid the effects caused by relative movements on the solar cells and electrodes, positive and negative electrodes of a solar cell are normally positioned on opposite sides of the solar cell for easier welding with electrodes of neighboring solar cells. However, high welding temperature on one side may lead to sealing-off or desoldering of the electrodes already welded on the opposite side, resulting in higher technical requirements for welding. Additionally, the solar cells contained in the existing solar battery assembly may not be rearranged and provide unadjustable voltage and current. Therefore, failure of one single cell may result in the malfunction of the whole solar battery assembly, thus bringing huge waste and great difficulty in maintenance.

### SUMMARY

Accordingly, the present disclosure provides a solar battery assembly, which may overcome the difficulty in electrode welding and desoldering with reduced cost and easy maintenance. In addition, the solar battery assembly disclosed herein may have stable performance and provide adjustable circuit configurations according to different operating conditions.

A solar battery assembly may be provided, comprising: a light transmitting upper cover plate; a carrier; a plurality of solar cells disposed between the light transmitting upper cover plate and the carrier. The solar cell may be connected to the carrier to form a positive connection point and a negative connection point. The plurality of solar cells may be connected in series, in parallel, or in combinations of both via the positive connection points and the negative connection points. The light transmitting upper cover plate, the carrier and the plurality of solar cells may be adhered together.

According to some embodiments of the present disclosure, the carrier may serve as a lower cover plate of the solar battery assembly. In some embodiments, the carrier may be interposed between the plurality of solar cells and a lower cover plate, and capable of forming connection points with the positive and negative electrodes.

According to some embodiments of the present disclosure, the solar cell may be connected to the carrier to create a positive connection point and a negative connection point, and the plurality of solar cells may be connected in series, in parallel or in combinations of both via the positive connection points and the negative connection points. In some embodiments, the solar cell may comprise a positive extraction electrode and a negative extraction electrode for extracting current, and the positive and negative extraction electrodes may be connected to the carrier to form the positive and negative connection points, respectively. The connection may be thereby more flexible and the circuit more stable. Particularly, the voltage and current provided by the solar battery assembly may be adjustable via regulating circuits or regulating components placed in the circuit. Meanwhile, the solar battery assembly may still function well by adjusting the circuit when one or more solar cells fail, without the failure of the whole solar battery assembly. Thus, the solar battery assembly may be repairable. Furthermore, the adjustment of the connection between solar cells may be simple and thereby avoid complex processes such as desoldering the solar cells to prevent damaging the solar cells. In addition, the solar cells may be replaced easily.

In the solar battery assembly disclosed herein, the plurality of solar cells may be connected via the positive and negative connection points formed by the positive and negative extraction electrodes connected to the carrier. The positive and negative connection points may be electrically connected via an internal connecting circuit formed on the upper and/or lower surface of the carrier or an external connecting circuit. Thereby, the solar battery assembly may avoid using conventional long welding strips which are sometimes about twice the length of the solar cells, but adopt shorter welding strips for secure welding and prevent shortcomings such as pseudo soldering with reduced cost. Meanwhile, the positive and negative extraction electrodes may be extracted from two ends of the solar cell. The single solar cell may be fixed via the fixation of the positive and negative extraction electrodes on the carrier; especially when the carrier serves as the lower cover plate of the solar battery assembly, the movement of the solar cells, and the damages to the solar cells caused by vibration, may therefore be prevented with enhanced the battery lifespan. In addition, the positive and negative extraction electrodes may be disposed on the front or back surface of the solar cell without special requirements on their positions, thus reducing the complexity and cost of the manufacturing process.

Additional aspects and advantages of the embodiments of the present disclosure will be given in part in the following descriptions, become apparent in part from the following descriptions, or be learned from the practice of the embodiments present disclosure.

### BRIEF DESCRIPTION OF THE DRAWINGS

These and other aspects and advantages of the present disclosure will become apparent and more readily appreciated from the following descriptions taken in conjunction with the drawings in which:

FIG. 1 is a cross-sectional view of a solar battery assembly according to a first embodiment of the present disclosure;

FIG. 2 is a cross-sectional view of a solar battery assembly according to a second embodiment of the present disclosure;

FIG. 3 is a schematic view of a carrier formed with electrode connection points of a solar battery assembly according to the first and second embodiments of the present disclosure;

FIG. 4 is a schematic view of the connection of solar cells with a carrier according to the first embodiment of the present disclosure;

FIG. 5 is a schematic view of the connection of solar cells with a carrier according to the second embodiment of the present disclosure;

FIG. 6 is a enlarged view of the connection of solar cells having a bypass diode with a carrier according to some embodiments of the present disclosure; and

FIG. 7 is a schematic view of a solar battery assembly according to the first and second embodiments of the present disclosure.

### DETAILED DESCRIPTION OF EMBODIMENTS

Reference will be made in detail to embodiments of the present disclosure. The embodiments described herein with reference to drawings are explanatory, illustrative, and used to generally understand the present disclosure. The embodiments shall not be construed to limit the present disclosure. The same or similar elements and the elements having same or similar functions are denoted by like reference numerals throughout the descriptions.

A solar battery assembly is provided, which may be adjustable and repairable and can be manufactured with reduced complexity. The solar battery assembly may comprise a light transmitting upper cover plate; a carrier; and a plurality of solar cells disposed between the light transmitting upper cover plate and the carrier. The solar cell may be connected to the carrier to form a positive connection point and a negative connection point. The plurality of solar cells may be connected in series, in parallel or in combinations of both via the positive and negative connection points. The light transmitting upper cover plate, the carrier and the plurality of solar cells may be adhered together, for example, via an adhesive or a binding agent.

According to some embodiments of the present disclosure, the solar cell may comprise a positive extraction electrode and a negative extraction electrode for extracting current, and the positive and negative extraction electrodes may be electrically connected to the carrier to form the positive connection point and the negative connection point, respectively. The positive and negative extraction electrodes may be connected directly to the carrier, to stabilize the connection and simplify the production process. Also the voltage of the solar battery assembly may be adjustable, and the solar battery assembly can also be repaired with easy maintenance.

According to some embodiments of the present disclosure, the positive connection points and the negative connection points may be electrically connected via a connecting circuit. In some embodiments, the connecting circuit may include an internal circuit configured on the upper surface and/or the lower surface of the carrier. Therefore, different connections of the solar cells, such as connections in series, in parallel or in combinations of both, may be achieved easily. According to some embodiments of the present disclosure, the positive and negative connection points may penetrate through the carrier to be connected by an external connecting circuit, thus achieving the connections and adjustment of the solar cells via the external connecting circuit which is not formed on the surface of the carrier. For example, the solar cells may be connected with each other in series by connecting the positive connection point of a solar cell with the negative connection point of an adjacent solar cell via the connecting circuit. The connecting circuit may be connected via normal wires, or formed by sintering a metal slurry on the carrier. Other electrical components, such as bypass diodes, may be arranged in the connecting circuit. According to some embodiments of the present disclosure, regulating elements, such as resistors and switching diodes, may also be arranged in the connecting circuit.

The light transmitting upper cover plate may be any type of upper cover plate commonly used in the art, such as a glass plate.

According to some embodiments of the present disclosure, the carrier may serve as a lower cover plate directly. According to some embodiments of the present disclosure, the carrier may be disposed between the solar cells and a lower cover plate, and connected with the positive and negative extraction electrodes to form the positive and negative connection points.

According to some embodiments of the present disclosure, the carrier serving as the lower cover plate may be selected from a back sheet commonly used in the art, for example, a back sheet made of Tedlar-Polyester-Tedlar (TPT) composite film, thermoplastic elastermor (TPE) composite film, Vitex Systems Barix™ Barrier Film (BBF) composite film, or polyimide (PI) composite film. According to some embodiments of the present disclosure, a printed circuit board (PCB), for example, an integrated circuit board formed by a chemical etching conductive film such as a copper foil, may be used as the lower cover plate of the solar battery assembly. The electrode connection points may thus be electrically connected directly via the integrated circuit of the PCB board. In some embodiments, other components, such as bypass diodes, may be arranged on the upper surface and/or the lower surface of the PCB board. According to some embodiments of the present disclosure, a hard lower cover plate, such as a glass plate and a steel plate, may be adopted, which may be easy to dispose circuits thereon and attached well with the upper cover plate to form a solar battery assembly having an attractive appearance and durable mechanical strength.

When the carrier serving as the lower cover plate is selected from a back sheet, a glass plate and a steel plate, according to some embodiments of the present disclosure, a metal slurry may be printed on the upper surface of the carrier, i.e. the inner surface of the lower cover plate of the solar battery assembly, and then sintered to form the connecting circuit. Therefore, the connection points may be connected easily, and the production process may be simplified with reduced cost. Particularly, because the connecting circuit is provided inside the solar battery assembly and subject to reduced influences from the external environment, the performance and lifespan of the solar battery assembly may be enhanced accordingly. It may also be easy to connect the solar cell with a bypass diode for further protection.

According to some embodiments of the present disclosure, the metal slurry may also be printed on the lower surface of the carrier and then sintered to form the connecting circuit. In some embodiments, the connecting circuit may be connected by wires on the lower surface of the carrier for easy operation and formation outside the solar battery assembly. According to some embodiments of the present disclosure, the carrier may be formed with connection points connected with the lower surface of the carrier. For example, a via-hole may be formed at the connection point, by which the positive and negative extraction electrodes may be connected with the carrier and penetrate through the carrier to be further connected via an external connecting circuit disposed outside the solar battery assembly. The current extraction electrodes may be attached to the carrier via an adhesive or a binding agent. The structure described hereinabove may provide tight fixation between the extraction electrodes and the solar cells, stabilizing the solar battery assembly and enhancing the battery lifespan.

According to some embodiments of the present disclosure, the carrier does not serve as the lower cover plate of the solar battery assembly, and the lower cover plate may be attached to the lower surface of the carrier. In some embodiments, the connecting circuit may be configured on the carrier, and the lower cover plate may function for encapsulation purposes without circuits formed thereon. There are no special limits on the material of the carrier. In some embodiments, the extraction electrodes may penetrate through the carrier at the connection points and connect with the connecting circuit formed on or outside the lower cover plate. The connecting circuit on or outside the lower cover plate may be configured in the same way as the connecting circuit formed on the carrier described herein without a special limit. The structure described above may stabilize the fixation of the solar cells to prevent the movements thereof. There is no special limit to the material and structure of the carrier for easy sealing of the solar battery assembly. In the solar battery assembly described herein, the solar cell may not be directly connected with the lower cover plate, especially not directly with the electrical components configured on the lower cover plate. The components may thereby be protected effectively to extend the lifespan of the solar battery assembly. There is no special limit to the kind of the lower cover plate. According to some embodiments of the present disclosure, it may be selected from a back sheet made of any material known in the art. In some embodiments, it may be selected from a glass plate and a steel plate.

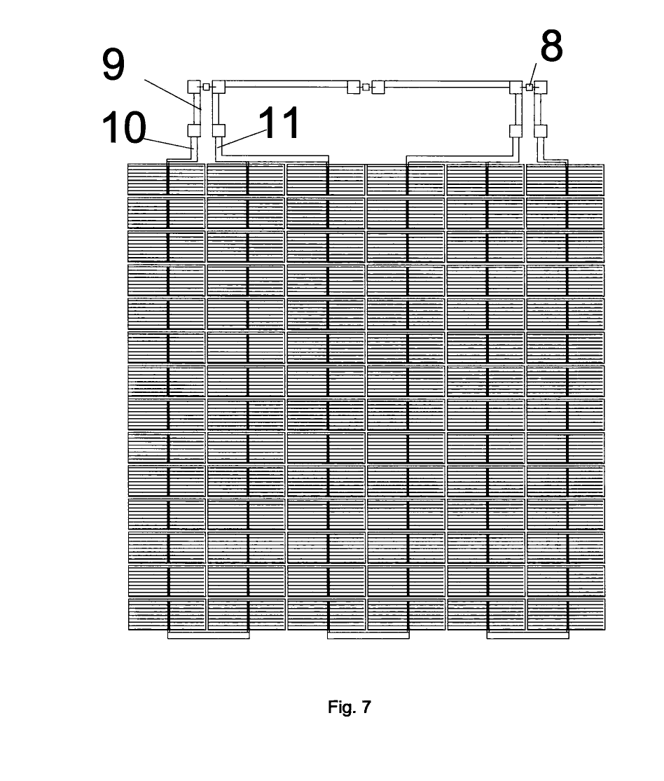

According to some embodiments of the present disclosure, at least one bypass diode may be connected in anti-parallel with the solar cells to prevent the hot spot effect. The bypass diodes may be disposed inside the solar battery assembly between the solar cells and the carrier, or between the carrier and the lower cover plate. According to some embodiments of the present disclosure, each solar cell may be connected with a bypass diode in parallel, and the bypass diode may be fixed between the solar cells to avoid reverse breakdown. According to some embodiments of the present disclosure, the bypass diodes may be arranged on the lower surface of the carrier or that of the lower cover plate, and connected in parallel with an array of solar cells as shown in FIG. 7. The at least one bypass diode may be connected with the carrier or the lower cover plate via welding or conductive adhesives. The bypass diodes may be connected in anti-parallel with the solar cells, wherein a positive electrode of the bypass diode is connected with the negative extraction electrode of the solar cell, and wherein a negative electrode of the bypass diode is connected with the positive extraction electrode of the solar cell.

According to some embodiments of the present disclosure, regulating components for circuit adjustment may be arranged in the circuit to adjust the voltage of the solar battery assembly. Therefore, the failure of a single solar cell may not impair the whole assembly. And other electrical components may be also adopted, such as resistors and switch triodes, to improve the stability and performance of the circuit. In some embodiments, in order to extend the lifespan of the components, a sealing agent may be coated on the components, or a sealing cover may be adopted to cover the components for circuit protection.

There is no special limit to the material of the positive and negative extraction electrodes, which can be selected from any type of extraction electrodes known in the art. The solar cells may be selected from any kind adopted in the art, such as multicrystalline silicon solar cells, monocrystalline silicon solar cells and thin-film solar cells.

In the solar battery assembly disclosed herein, the positive and negative extraction electrodes may be led out from two ends of the solar cell, respectively. In some embodiments, the positive extraction electrode may be attached to back surface grid lines of the solar cell; the negative extraction electrode may be attached to front surface grid lines of the solar cell. The method of attachment may be any kind known in the art, such as tin soldering, and attaching via a conductive adhesive agent. There is no special limit to the position of the electrode grid lines. In some embodiments, the front and back surface grid lines may be disposed at corresponding positions on the front and the back surface of the solar cells, respectively. In some embodiments, the front and back surface grid lines may not be configured at corresponding positions on the front and back surfaces to reduce processing difficulty.

According to some embodiments of the present disclosure, no circuit may be configured outside the solar battery assembly to reduce external influence on the circuit and improve the battery performance and lifespan. In addition, the bypass diode for bypass protection may be connected easily with simplified manufacturing processes suitable for large scale production.

According to some embodiments of the present disclosure, the adhesive or binding agent may be selected from, for example, polyvinyl butyral (PVB) resin and ethylene-vinyl acetate (EVA), which may be filled between the upper cover plate and the solar cells, and between the solar cells and the carrier or the lower cover plate. According to some embodiments of the present disclosure, polyvinyl butyral resin(PVB) may be adopted, which has excellent light transmittance, weatherability and UV resistance in addition to an expansion coefficient close to that of the solar cell after adhesion. Accordingly, in some embodiments, at room temperature or a lower temperature, PVB films may be disposed between the laminated light transmitting upper cover plate, the plurality of solar cells, and the carrier or the lower cover plate. Then after vacuumizing and hot pressing the laminated layers, the PVB films may be melted and filled in the space of the solar battery assembly to form an integrated body. In some embodiments, liquid PVB may be filled in the solar battery assembly to shape and encapsulate the solar battery assembly and to simply the production process and stabilize the connections. Moreover, the binding agent with such a sealing function may enhance the strength and stability of the welding points, and extend the lifespan of the electrical components.

According to some embodiments of the present disclosure, the solar battery assembly may further comprise a sealing member for sealing the laminated light transmitting cover plate, the plurality of solar cells and the carrier, in order to be waterproof and dustproof, and avoid external influence on the performance and lifespan of the solar battery assembly. In some embodiments, a sealant may be filled between the sealing member and the components of the solar battery assembly. The sealing member may be formed with a groove for accommodating edges of the light transmitting upper cover plate, the plurality of solar cells and the carrier with the sealant filled therein, providing a waterproof and dustproof tight sealing effect. In addition, the solar battery assembly thus configured may be especially suitable for power devices subject to long-time vibrations such as vehicles. The solar battery assembly disclosed herein may effectively avoid the loosening of the sealing member due to vibrations, and thus further improve the performance and lifespan of the solar battery assembly. The sealant may be selected from any type known in the art, such as silica gel and epoxy resin.

The solar battery assembly disclosed herein may be of any shape known in the art.

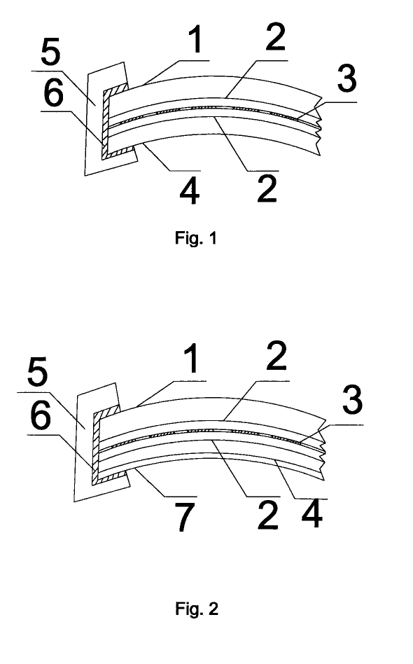

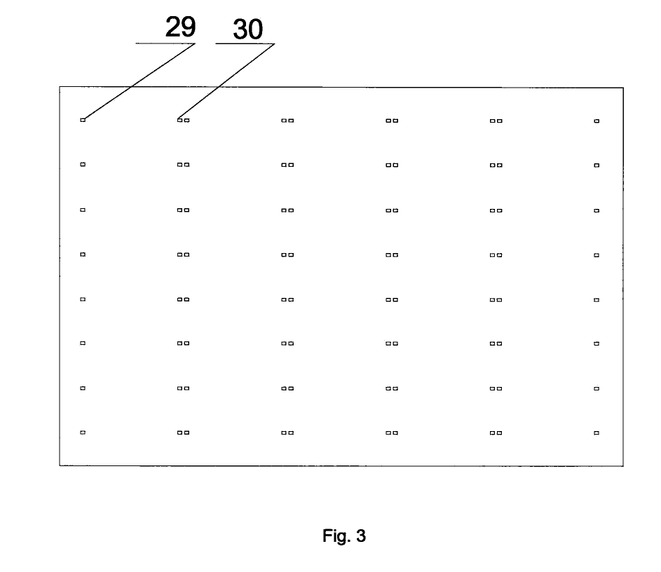

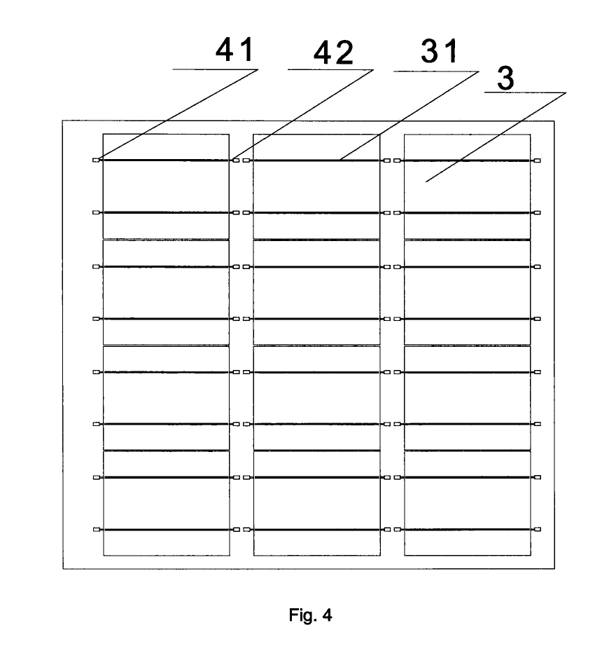

According to a first exemplary embodiment shown in FIGS. 1, 3, 4 and 7, a glass plate 1, a PVB film 2, a plurality of solar cells 3, a PVB film 2, and a carrier 4 being a glass plate formed with printed and sintered metal slurry circuit are overlapped and heat sealed. A sealing member 5 formed with a groove is fixed around and encapsulates the laminated layers. A layer of adhesive 6 is filled inside the groove of the sealing member 5 to form a solar battery assembly. As shown in FIG. 7, a positive electrode 10 and a negative electrode 11 of the solar battery assembly are led out for extracting current. At least one bypass diode 8 is connected in anti-parallel with the positive electrode 10 and the negative electrode 11 respectively. A positive extraction electrode 31 and a negative extraction electrode 32 are led out from two ends of the solar cell 3, respectively. One end of the positive extraction electrode 31 is welded to grid lines on the back surface of the solar cell, and the other end penetrates through the PVB film 2 and is welded to the carrier 4 to form a positive connection point 41. One end of the negative extraction electrode 32 is welded to grid lines on the front surface of the solar cell 3, and the other end penetrates through the PVB film 2 and is welded to the carrier 4 to form the negative connection point 42. A plurality of positive connection points 41 and a plurality of negative connection points 42 are electrically connected via a circuit on the surface of the carrier 4 so that the plurality of solar cells may be connected in series, in parallel or in combinations of both. The positive and negative extraction electrodes 31 and 32 of one solar cell 3 are located at the corresponding positions on the back surface and the front surface of the solar cell 3, respectively.

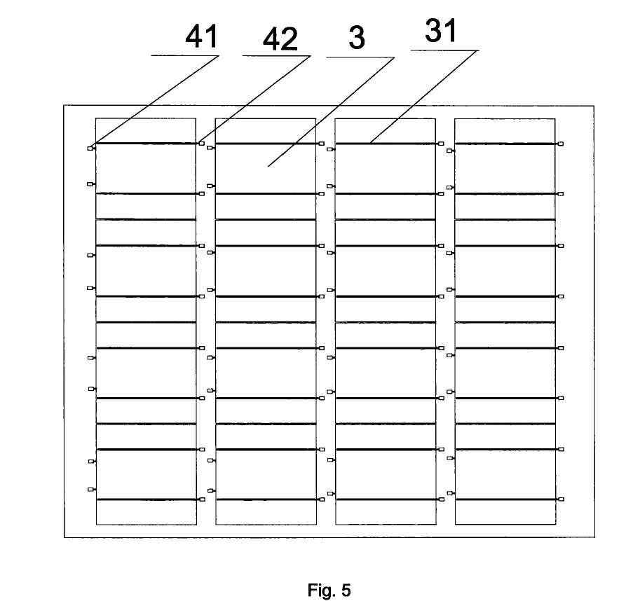

According to a second exemplary embodiment shown in FIGS. 2, 3, 5 and 7, a glass plate 1, a PVB film 2, a plurality of solar cells 3, a PVB film 2, a carrier 4 for insulation and fixation formed with via-holes, and a PCB board 7 having circuits formed thereon are overlapped and heat sealed. A sealing member 5 formed with a groove is fixed around and encapsulates the laminated layers. A layer of adhesive 6 is filled inside the groove of the sealing member 5 to form a solar battery assembly. As shown in FIG. 7, a positive electrode 10 and a negative electrode 11 of the solar battery assembly are led out for extracting current. At least one bypass diode 8 is connected in anti-parallel with the positive electrode 10 and the negative electrode 11 respectively. A positive extraction electrode 31 and a negative extraction electrode 32 are led out from two ends of the solar cell 3 respectively. One end of the positive extraction electrode 31 is welded to grid lines on the back surface of the solar cell 3, and the other end penetrates through the PVB film 2 and is welded to the carrier 4 to form a positive connection point 41. One end of the negative extraction electrode 32 is welded to grid lines on the front surface of the solar cell 3, and the other end penetrates through the PVB film 2 and is welded to the carrier 4 to form the negative connection point 42. A plurality of the positive connection points 41 and a plurality of the negative connection points 42 are electrically connected via a circuit on the surface of the carrier 4 so that the plurality of solar cells are connected in series, in parallel or in combinations of both. The positive and negative extraction electrodes 31 and 32 of one solar cell 3 are located at positions not corresponding to each other on the back and front surfaces of the solar cell 3, respectively, which may benefit the welding of the extraction electrodes with the grid lines without causing problems such as sealing-off and poor soldering.

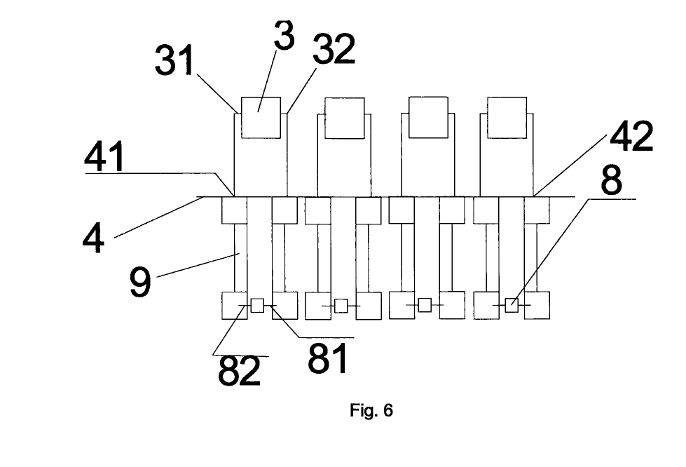

FIG. 6 shows an enlarged view of the connections between the solar cells 3 having an anti-parallel connected bypass diode 8 and the carrier 4. A positive extraction electrode 31 and a negative extraction electrode 32 are led out from the two ends of the solar cell 3, respectively, and are further welded with the carrier 4 to form a positive connection point 41 and a negative connection point 42 on the lower surface of the carrier 4, respectively. A bypass diode 8 is connected in anti-parallel with each solar cell 3 on the lower surface of the carrier 4. A positive electrode 81 of the bypass diode 8 is connected with the negative connection point 42 on the carrier 4 via a wire-welding electrode 9, and a positive electrode 82 of the bypass diode 8 is connected with the negative connection point 41 of the carrier 4 via another wire-welding electrode 9, so that the bypass diode 8 is connected in anti-parallel with the solar cell 3.

Although explanatory embodiments have been shown and described, it would be appreciated by those skilled in the art that changes, alternatives, and modifications can be made in the embodiments without departing from spirit and principles of the present disclosure. Such changes, alternatives, and modifications all fall into the scope of the claims and their equivalents.

What is claimed is:

1. A solar battery assembly, comprising:
a light transmitting upper cover plate;
a carrier;
a plurality of solar cells disposed between the light transmitting upper cover plate and the carrier, wherein
the solar cell is connected to the carrier to form a positive connection point and a negative connection point, and wherein
the plurality of solar cells are connected in series, in parallel or in combinations of both via the positive connection points and the negative connection points.

2. The solar battery assembly according to claim 1, wherein the solar cell comprises a positive extraction electrode and a negative extraction electrode to extract currents which are electrically connected to the carrier to form the positive connection point and the negative connection point respectively.

3. The solar battery assembly according to claim 1, wherein the positive connection points and the negative connection points are electrically connected via an connecting circuit configured on the upper surface and/or the lower surface of the carrier.

4. The solar battery assembly according to claim 1, wherein the light transmitting cover plate is a glass plate.

5. The solar battery assembly according to claim 1, wherein the carrier is selected from a back sheet made of TPT composite membrane, TPE composite membrane, BBF composite membrane and PI composite membrane.

6. The solar battery assembly according to claim 3, wherein the carrier includes a printed circuit board with the connecting circuit being formed thereon.

7. The solar battery assembly according to claim 3, wherein the carrier is selected from a glass plate and a steel plate with the connecting circuit being formed thereon.

8. The solar battery assembly according to claim 3, wherein the connecting circuit is formed by printing and sintering a metal slurry on the surface of the carrier.

9. The solar battery assembly according to claim 3, wherein the connecting circuit is connected by wires and configured on the lower surface of the carrier.

10. The solar battery assembly according to claim 2, wherein the positive and negative connection points are electrically connected with the lower surface of the carrier, and the positive and negative extraction electrodes are configured to form an exterior connecting circuit.

11. The solar battery assembly according to claim 10, wherein a via-hole is formed at the connection point, through which the extraction electrodes are connected with the carrier.

12. The solar battery assembly according to claim 1, further comprising a lower cover plate disposed on the lower surface of the carrier.

13. The solar battery assembly according to claim 12, wherein the lower cover plate is selected from a back sheet, a glass plate and a steel plate.

14. The solar battery assembly according to claim 1, wherein the solar cell is connected in anti-parallel with a bypass diode disposed on the lower surface of the carrier.

15. The solar battery assembly according to claim 12, wherein the solar cell is connected in anti-parallel with a bypass diode disposed on the lower surface of the lower cover plate

16. The solar battery assembly according to claim 1, wherein the light transmitting upper cover plate, the plurality of solar cells and the carrier are adhered together via an adhesive or a binding agent.

17. The solar battery assembly according to claim 1, further comprising a sealing member for sealing the light transmitting upper cover plate, the plurality of solar cells and the carrier.

18. The solar battery assembly according to claim 17, wherein the sealing member is formed with a groove for accommodating edges of the light transmitting upper cover plate, the plurality of solar cells and the carrier with a sealant being filled therein.

19. The solar battery assembly according to claim 3, wherein the connecting circuit comprises at least one regulating component for circuit adjustment.

20. The solar battery assembly according to claim 1, wherein the positive connection points and the negative connection points are electrically connected via an external connecting circuit configured outside the solar battery assembly.
